(19) United States
(12) Patent Application Publication
(10) Pub. No.: US 2017/0052458 A1
(43) Pub. Date: Feb. 23, 2017

(54) DIFFRACTIVE OVERLAY MARK

(71) Applicant: GLOBALFOUNDRIES Inc., Grand Cayman, KY (US)

(72) Inventor: Ming Hao TANG, Ballston Lake, NY (US)

(21) Appl. No.: 14/831,920

(22) Filed: Aug. 21, 2015

(51) Int. Cl. G03F 7/20; G02B 5/18; G01N 21/47; G02B 27/42

(52) U.S. Cl. CPC G03F 7/70633; G02B 27/4266; G02B 5/1847; G01N 21/4788; G01N 2201/12

(57) ABSTRACT

A method and apparatus for calculating overlay based on high order diffraction phase measurements are provided. Embodiments include forming a first diffraction pattern in a first layer of a wafer; forming a second diffraction pattern in a second layer of the wafer, the second layer being formed over the first layer; detecting a first or a higher odd order signal in an X and a Y direction from each of the first and second diffraction patterns; calculating a peak for each signal; measuring a delta value between peaks of the signals in the X direction and a delta value between peaks of the signals in the Y direction; and calculating an overlay between the first and second layers based on the delta values.

### TECHNICAL FIELD

The present disclosure relates to semiconductor device overlay measurement processes. The present disclosure is particularly applicable to semiconductor devices formed by lithography.

### BACKGROUND

Current overlay measurement concepts pose a number of challenges to designers of increasingly small technology nodes. For example, adverting to FIG. 1A, box in box (BIB), a traditional image based overlay mark, requires a big pattern 101, which can cause a chemical mechanical polishing (CMP) issue. Also, an asymmetric design profile can cause overlay shift; a capture image is required; and the overall accuracy is not that good. Advanced Imaging Metrology (AIM) and Blossom are also image based overlay marks, as depicted in FIGS. 1B and 1C, respectively. AIM uses an average of multiple lines 103 to increase measurement precision. While the accuracy of AIM is better than BIB or Blossom due to being multi-image based, the overall accuracy is limited by image resolution. In addition, like BIB, a big pattern is required, which can cause a CMP issue; an asymmetric design profile can cause overlay shift; and a capture image is required. Blossom marks 105 are small to save space. However, there are no labels, which can make it difficult to find the measurement layer; the small size of the pattern can cause the measurement accuracy to suffer; and Blossom is single image based. Adverting to FIG. 1D, another overlay concept, diffraction based overlay (DBO), is diffraction intensity based rather than image based. Generally, DBO involves first order data, +d/−d intensities are compared, and the working range is small due to sine curve response. However, the resulting measurement data is only available for the first order; two measurement pads 107 (1^{st} exposure, no bias) and 109 (2^{nd} exposure, bias target) are required to measure the overlay; and the results can be impacted by discoloration. Images 111 and 113 are cross-section views of the measurement pads 107 and 109, respectively.

A need therefore exists for methodology and apparatus enabling high order diffraction based overlay measurements.

### SUMMARY

An aspect of the present disclosure is a method of calculating overlay based on high order diffraction phase measurements.

Another aspect of the present disclosure is an apparatus for calculating overlay based on high order diffraction phase measurements.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: forming a first diffraction pattern in a first layer of a wafer; forming a second diffraction pattern in a second layer of the wafer, the second layer being formed over the first layer; detecting a first or a higher odd order signal in an X and a Y direction from each of the first and second diffraction patterns; calculating a peak for each signal; measuring a delta value between peaks of the signals in the X direction and a delta value between peaks of the signals in the Y direction; and calculating an overlay between the first and second layers based on the delta values.

Aspects of the present disclosure include forming the first diffraction pattern with a pitch of 80 nanometer (nm) to 800 nm. Other aspects include forming the second diffraction pattern with a pitch of 160 nm to 1600 nm. Further aspects include forming the second diffraction pattern overlapping the first diffraction pattern in a parallel direction, a perpendicular direction, or a parallel and perpendicular direction to the first diffraction pattern. Additional aspects include detecting the first or higher odd order signal in the X and Y directions from each of the first and second diffraction patterns by: scanning the first and second diffraction patterns in the X direction with a laser; detecting a first square wave from the first and second diffraction patterns; decomposing the first square wave into the first or higher odd order signal for each of the first and second diffraction patterns in the X direction; scanning the first and second diffraction patterns in the Y direction with a laser; detecting a second square wave from the first and second diffraction patterns; and decomposing the second square wave into the first or higher odd order signal for each of the first and second diffraction patterns in the Y direction. Another aspect includes decomposing the first and second square waves using a Fourier Transform equation. Other aspects include forming the second diffraction pattern without overlapping the first diffraction pattern. Further aspects include detecting the first or higher odd order signal in the X and Y directions from each of the first and second diffraction patterns by: scanning the first and second diffraction patterns in the X direction with a laser; detecting a first and a second square wave from the first and second diffraction patterns; decomposing the first and the second square wave into first and second first or higher odd order signals for each of the first and second diffraction patterns in the X direction; scanning the first and second diffraction patterns in the Y direction with a laser; detecting a third and a fourth square wave from the first and second diffraction patterns; decomposing the third and fourth square waves into third and fourth first or higher odd order signals for each of the first and second diffraction patterns in the Y direction. Additional aspects include decomposing the first, second, third, and fourth square waves using a Fourier Transform equation.

Another aspect of the present disclosure is an apparatus including: a processor; and a memory including computer program code for one or more programs, the memory and the computer program code configured to, with the processor, cause the apparatus to perform the following, form a first diffraction pattern in a first layer of a wafer; form a second diffraction pattern in a second layer of the wafer, the second layer being formed over the first layer; detect a first or a higher odd order signal in an X and a Y direction from each of the first and second diffraction patterns; calculate a peak for each signal; measure a delta value between peaks of the signals in the X direction and a delta value between peaks of the signals in the Y direction; and calculate an overlay between the first and second layers based on the delta values.

Aspects of the apparatus include the apparatus being further caused to: form the first diffraction pattern with a pitch of 80 nm to 800 nm. Other aspects include the apparatus being further caused to: form the second diffraction pattern with a pitch of 160 nm to 1600 nm. Further aspects include the apparatus being further caused to: form the second diffraction pattern overlapping the first diffraction pattern in a parallel direction, a perpendicular direction, or a parallel and perpendicular direction to the first diffraction pattern. Additional aspects include the apparatus being further caused, with respect to detecting the first or higher odd order signal in the X and Y directions from each of the first and second diffraction patterns, to: scan the first and second diffraction patterns in the X direction with a laser; detect a first square wave from the first and second diffraction patterns; decompose the first square wave into the first or higher odd order signal for each of the first and second diffraction patterns in the X direction; scan the first and second diffraction patterns in the Y direction with a laser; detect a second square wave from the first and second diffraction patterns; and decompose the second square wave into the first or higher odd order signal for each of the first and second diffraction patterns in the Y direction. Another aspect includes the apparatus being further caused to: decompose the first and second square waves using a Fourier Transform equation. Other aspects include the apparatus being further caused to: form the second diffraction pattern without overlapping the first diffraction pattern. Further aspects include the apparatus is further caused, with respect to detecting the first or higher odd order signal in the X and Y directions from the first and second diffraction patterns, to: scan the first and second diffraction patterns in the X direction with a laser; detect a first and a second square wave from the first and second diffraction patterns; decompose the first and the second square wave into first and second first or higher odd order signals for each of the first and second diffraction patterns in the X direction; scan the first and second diffraction patterns in the Y direction with a laser; detect a third and a fourth square wave from the first and second diffraction patterns; decompose the third and fourth square waves into third and fourth first or higher odd order signals for each of the first and second diffraction patterns in the Y direction. Additional aspects include the apparatus being further caused to: decompose the first, second, third, and fourth square waves using a Fourier Transform equation.

A further aspect of the present disclosure is a method including: forming a first diffraction pattern with a pitch of 80 nm to 800 nm in a first layer of a wafer; forming a second diffraction pattern with a pitch of 160 nm to 1600 nm in a second layer of the wafer, the second diffraction pattern overlapping the first diffraction pattern in a parallel direction, a perpendicular direction, or a parallel and perpendicular direction to the first diffraction pattern; detecting a first or a higher odd order signal in an X and a Y direction from the first and second diffraction patterns; calculating a peak for each signal; measuring a delta value between peaks of the signals in the X direction and a delta value between peaks of the signals in the Y direction; and calculating an overlay between the first and second layers based on the delta values. Aspects of the present disclosure include detecting the first or higher odd order signal in the X and Y directions from each of the first and second diffraction patterns by: scanning the first and second diffraction patterns in the X direction with a laser; detecting a first square wave from the first and second diffraction patterns; decomposing the first square wave into the first or higher odd order signal for each of the first and second diffraction patterns in the X direction using a Fourier Transform equation; scanning the first and second diffraction patterns in the Y direction with a laser; detecting a second square wave from the first and second diffraction patterns; and decomposing the second square wave into the first or higher odd order signal for each of the first and second diffraction patterns in the Y direction using the Fourier Transform equation.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIGS. 1A through 1D schematically illustrate current overlay design marks;

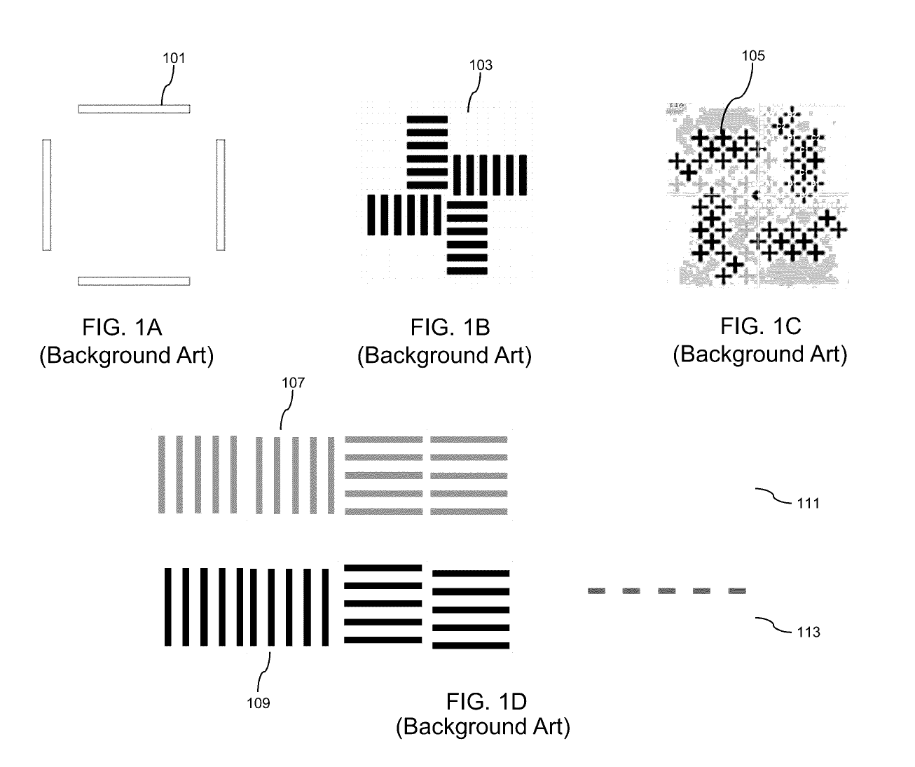

FIG. 2 depicts a diffraction based overlay measurement process flow, in accordance with an exemplary embodiment;

FIGS. 3A through 3C schematically illustrate example overlapped pre-layer and current layer diffraction patterns arranged in the X and Y directions, in accordance with an exemplary embodiment;

FIG. 3D schematically illustrates an example non-overlapped pre-layer and current layer diffraction pattern arranged in the X and Y directions, in accordance with an exemplary embodiment;

FIG. 4 illustrates example square waves and first order signals resulting from scanning the pre-layer and current layer pattern of FIG. 3A in the X direction, in accordance with an exemplary embodiment; and

FIGS. 5A and 5B schematically illustrate an example non-overlapped pre-layer and current layer diffraction pattern arranged in the X and Y directions and corresponding segmented pre-layer and current layer diffraction patterns arranged in the X and Y directions, respectively, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problems of imprecise overlay measurement, reduced throughput resulting from traditionally required image recognition steps, and congested wafer designs attendant upon forming semiconductor devices using lithography and conventional overlay concepts.

Methodology in accordance with embodiments of the present disclosure includes forming a first diffraction pattern in a first layer of a wafer. A second diffraction pattern is formed in a second layer of the wafer, the second layer being formed over the first layer. A first or a higher odd order signal is detected in an X and a Y direction from each of the first and second diffraction patterns. A peak is calculated for each signal. A delta value between peaks of the signals in the X direction and a delta value between peaks of the signals in the Y direction are measured. An overlay between the first and second layers is calculated based on the delta values.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

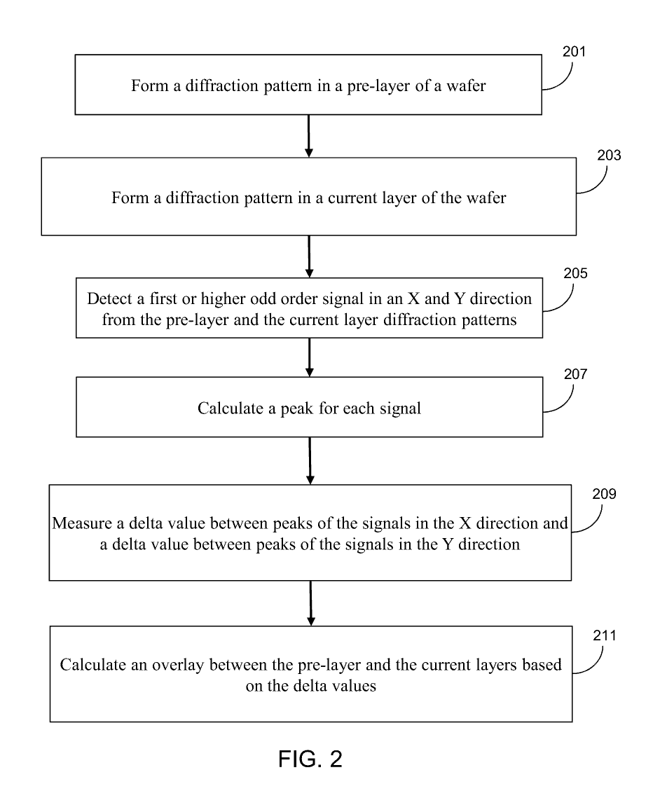

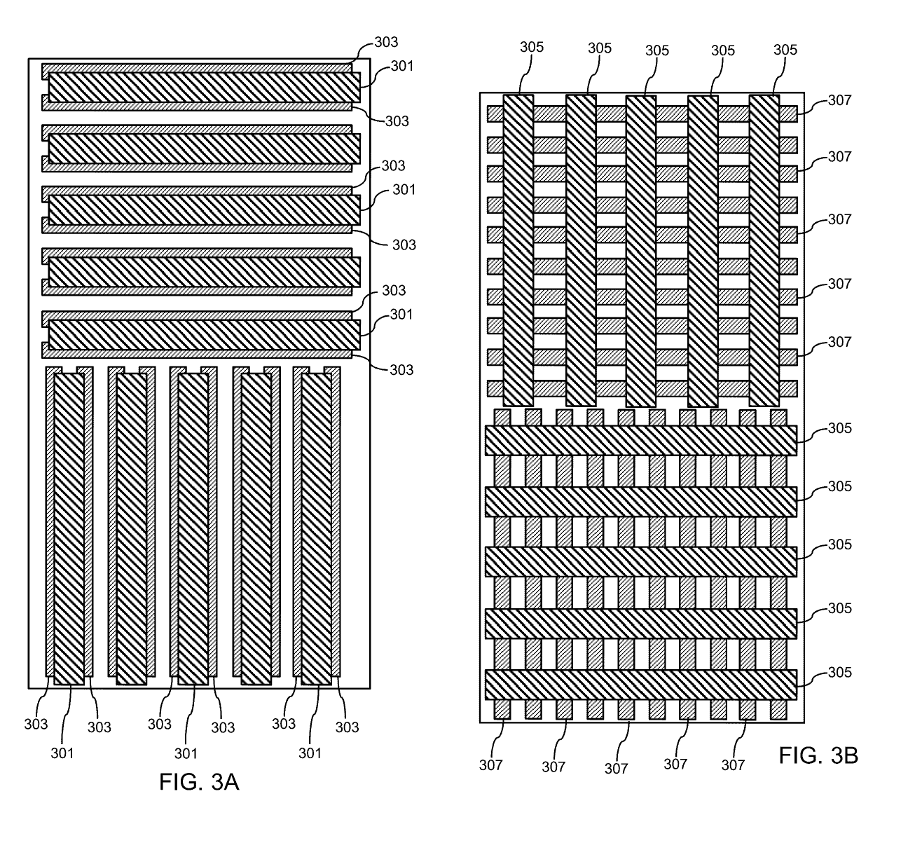

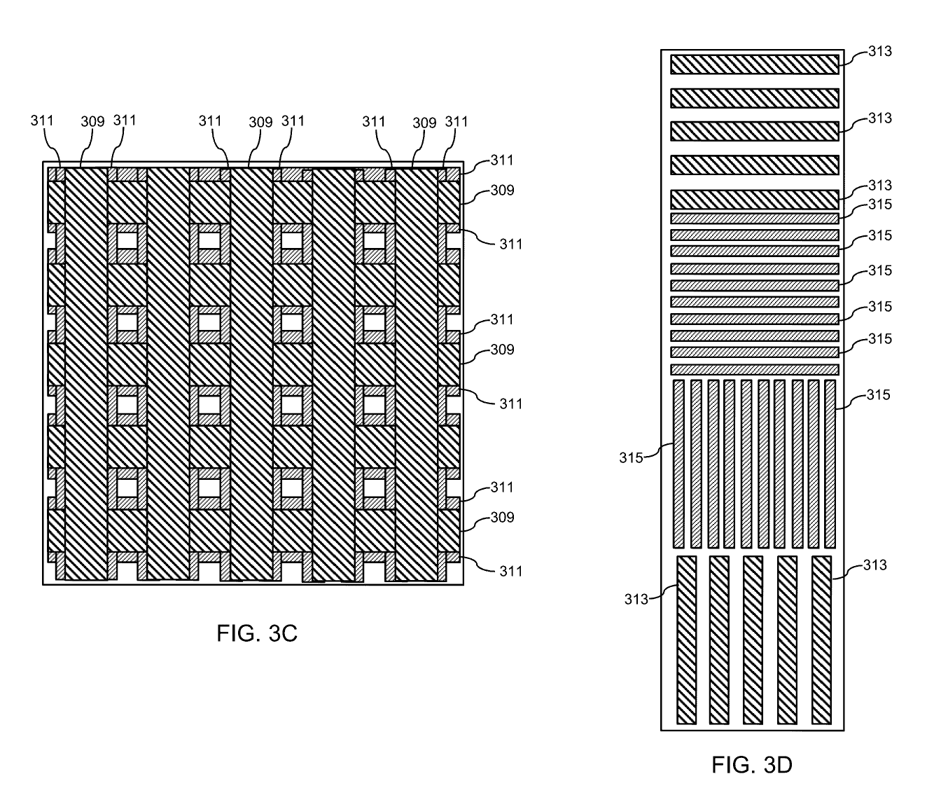

FIG. 2 depicts a diffraction based overlay measurement process flow, in accordance with an exemplary embodiment. In step 201, a diffractive pattern is formed in a pre-layer of a wafer in the X and Y directions. The pre-layer diffraction pattern may be formed, for example, with a pitch (P1) of 80 nm to 800 nm or more, e.g., equal to the wavelength of the detector. In step 203, a second diffractive pattern is formed in a current layer of the wafer in the X and Y directions. The current layer diffraction pattern may be formed, for example, with a pitch (P2=2×P1) of 160 nm to 1600 nm or more. The pitch of the current layer may also be 4×P1 or 6×P1 or another even multiple depending on the particular application. The current layer diffraction pattern may be formed, for example, by overlapping the pre-layer diffraction pattern in a parallel direction, a perpendicular direction, or a parallel and perpendicular direction to the pre-layer diffraction pattern. For example, the current layer diffraction pattern 301 of FIG. 3A overlaps the pre-layer diffraction pattern 303 in a parallel direction to the pre-layer diffraction pattern 303; the current layer diffraction pattern 305 of FIG. 3B overlaps the pre-layer diffraction pattern 307 in a perpendicular direction to the pre-layer diffraction pattern 307; and the current layer diffraction pattern 309 of FIG. 3C overlaps the pre-layer diffraction pattern 311 in a parallel and perpendicular direction to the pre-layer diffraction pattern 311. The current layer diffraction pattern may also be formed, for example, apart from and/or without overlapping the pre-layer diffraction pattern. For example, the current layer diffraction pattern 313 of FIG. 3D is formed apart from and/or without overlapping the pre-layer diffraction pattern 315.

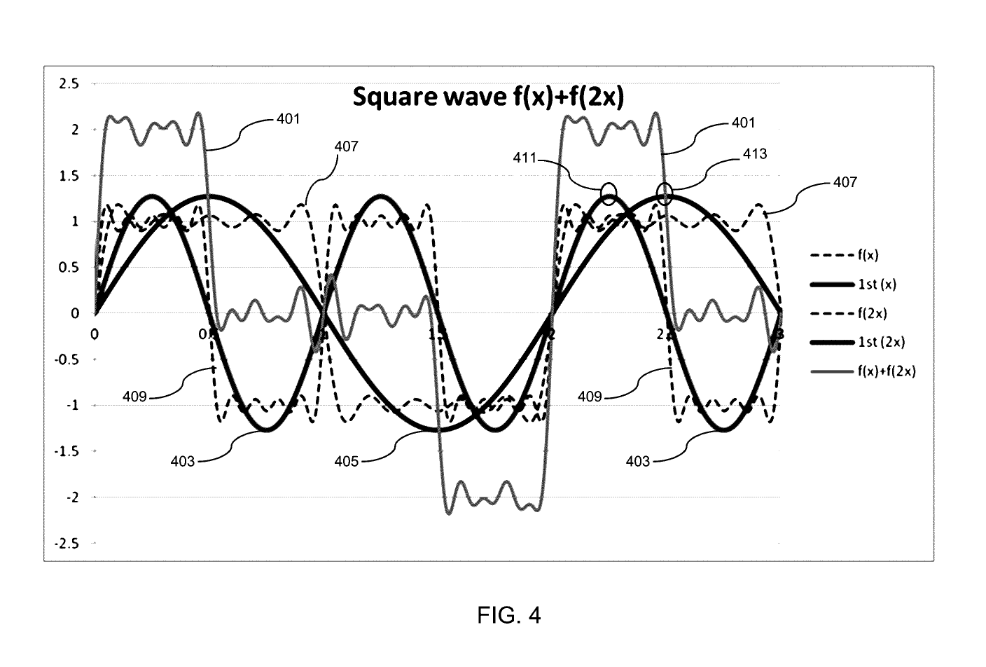

In step 205, a first or higher odd order signal is detected in the X and Y direction for each of the pre-layer diffraction pattern and the current layer diffraction pattern. For example, adverting to FIG. 3A, the pre-layer diffraction pattern 303 and the current layer 301 are scanned in the X direction with a laser. The resulting measurement pattern is a square wave 401 (f(x)+f(2x)), as depicted in FIG. 4. Using a Fourier Transform equation:

$$f ( x ) = \frac{4}{π} {\sum }_{n = 1 , 3 , 5 …}^{∞} \frac{1}{n} sin ( \frac{n π x}{L} ) ,$$

where n corresponds to the order, the square wave 401 can be decomposed to a first order or higher sine curve or wave, e.g., the first order sine curve 403 (1^{st}(x)), corresponding to the pre-layer diffraction pattern 303, and a first order or higher sine curve or wave, e.g., the first order sine curve 405 (1^{st}(2x)), corresponding to the current layer diffraction pattern 301. Putting the square wave f(x) and f(2x) together enables the first order signal to be determined from each wave because the first order of f(2x) is the second order of f(x), which has no intensity from f(x). The dotted lines 307 and 309 represent hypothetical square waves f(x) and f(2x), respectively, since this information cannot be directly determined from scanning the overlapped pre-layer diffraction pattern 303 and the current layer diffraction pattern 301. However, adverting to FIG. 3D, where the current layer diffraction pattern 313 is formed without overlapping the pre-layer diffraction pattern 315, the respective square waves could be detected for the pre-layer diffraction pattern and the current layer diffraction pattern and then decomposed to sine curves using the Fourier Transform equation. In both the examples of overlapping layers and non-overlapping layers, the steps of scanning, detecting, and decomposing are then repeated for the pre-layer diffraction pattern and the current layer diffraction pattern in the Y direction. The first order signature in the Y direction is the same as the first order signature in the X direction, except the signature is rotated 90°.

In step 207, a peak is calculated for the first or higher order sine curve corresponding to the pre-layer diffraction pattern in the X direction, e.g., peak 411 of the sine wave 403, and a peak is calculated for the first or higher order sine curve corresponding to the current layer diffraction pattern in the X direction, e.g., peak 413 of the sine wave 405. The peaks for the corresponding sine waves in the Y direction (not shown for illustrative convenience) are also calculated the same way.

In step 209, the delta value between peaks of the signals in the X direction, e.g., peaks 411 and 413, and the delta value between peaks of the signals in the Y direction are measured. Thereafter, in step 211, the overlay between the pre-layer diffraction pattern and the current layer diffraction pattern, e.g., the pre-layer diffraction pattern 303 and the current layer diffraction pattern 301, is calculated based on the delta values measured in step 209. For example, given a fixed offset between the center of two layer patterns, e.g., the pre-layer diffraction pattern 303 and the current layer diffraction pattern 301, the overlay between the two patterns equals the measured delta value minus the fixed offset.

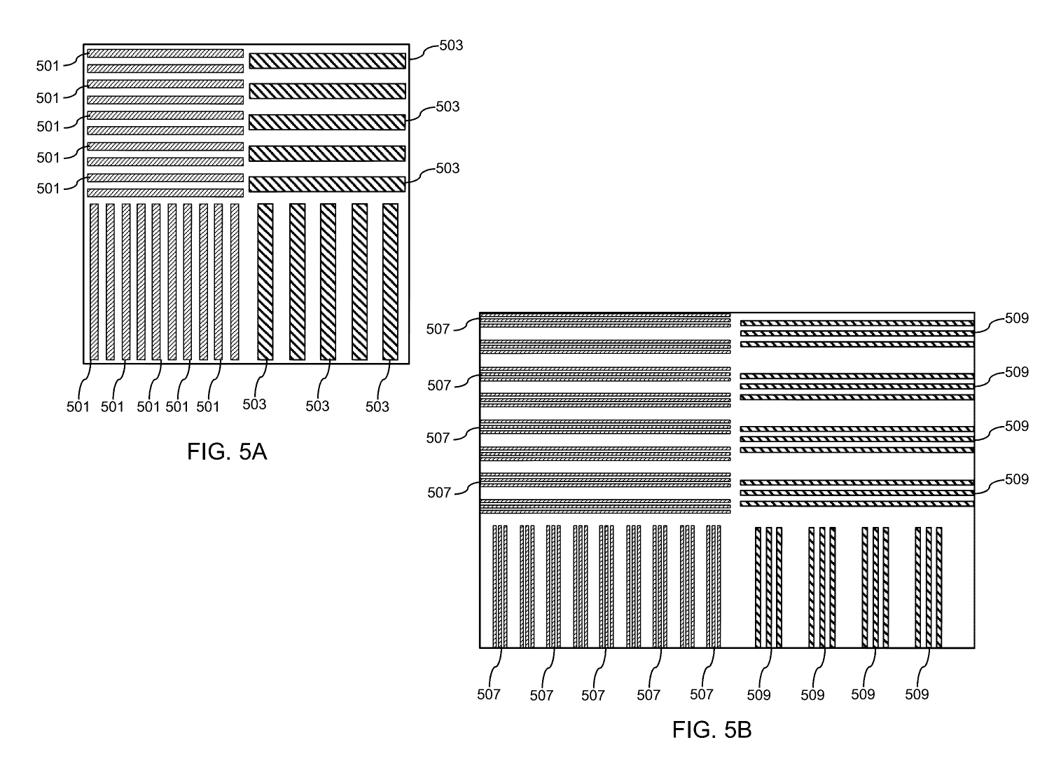

In addition to changing the n value of the Fourier Transform equation to determine higher orders, extra segments can also be added to a diffraction pattern to increase the high order intensity. For example, each line of the pre-layer diffraction pattern 501 and the current layer diffraction pattern 503, as depicted in FIG. 5A, can be segmented, for example, into three lines, as depicted by the corresponding segmented pre-layer diffraction pattern 505 and the corresponding segmented current layer diffraction pattern 507 of FIG. 5B. Consequently, the segmented pre-layer diffraction pattern 505 and the segmented current layer diffraction pattern 507 will enhance the 5^{th} order intensity and will enable better detectability of the 5^{th} order.

The embodiments of the present disclosure can achieve several technical effects including being diffraction based and taking advantage of the whole pattern, which increases measurement precision; needing no image capture, which can significantly improve throughput; having almost unlimited layout flexibility, e.g., x1, x2, y1, and y2 are independent with no crosstalk; saving considerable space; being wave based and, therefore, not impacted by substrate discoloration; and having the possibility of high orders, which is better for an asymmetric mark (caused by the process). Embodiments of the present disclosure enjoy utility in various industrial applications as, for example, microprocessors, smart phones, mobile phones, cellular handsets, set-top boxes, DVD recorders and players, automotive navigation, printers and peripherals, networking and telecom equipment, gaming systems, and digital cameras. The present disclosure therefore enjoys industrial applicability in any of various types of highly integrated semiconductor devices formed by lithography.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming a first diffraction pattern in a first layer of a wafer;
forming a second diffraction pattern in a second layer of the wafer, the second layer being formed over the first layer;
detecting a first or a higher odd order signal in an X and a Y direction from each of the first and second diffraction patterns;
calculating a peak for each signal;
measuring a delta value between peaks of the signals in the X direction and a delta value between peaks of the signals in the Y direction; and
calculating an overlay between the first and second layers based on the delta values.

2. The method according to claim 1, comprising forming the first diffraction pattern with a pitch of 80 nanometer (nm) to 800 nm.

3. The method according to claim 1, comprising forming the second diffraction pattern with a pitch of 160 nm to 1600 nm.

4. The method according to claim 1, comprising forming the second diffraction pattern overlapping the first diffraction pattern in a parallel direction, a perpendicular direction, or a parallel and perpendicular direction to the first diffraction pattern.

5. The method according to claim 4, comprising detecting the first or higher odd order signal in the X and Y directions from each of the first and second diffraction patterns by:
scanning the first and second diffraction patterns in the X direction with a laser;
detecting a first square wave from the first and second diffraction patterns;
decomposing the first square wave into the first or higher odd order signal for each of the first and second diffraction patterns in the X direction;
scanning the first and second diffraction patterns in the Y direction with a laser;
detecting a second square wave from the first and second diffraction patterns; and
decomposing the second square wave into the first or higher odd order signal for each of the first and second diffraction patterns in the Y direction.

6. The method according to claim 5, comprising decomposing the first and second square waves using a Fourier Transform equation.

7. The method according to claim 1, comprising forming the second diffraction pattern without overlapping the first diffraction pattern.

8. The method according to claim 7, comprising detecting the first or higher odd order signal in the X and Y directions from each of the first and second diffraction patterns by:
scanning the first and second diffraction patterns in the X direction with a laser;
detecting a first and a second square wave from the first and second diffraction patterns;
decomposing the first and the second square wave into first and second first or higher odd order signals for each of the first and second diffraction patterns in the X direction;
scanning the first and second diffraction patterns in the Y direction with a laser;
detecting a third and a fourth square wave from the first and second diffraction patterns;
decomposing the third and fourth square waves into third and fourth first or higher odd order signals for each of the first and second diffraction patterns in the Y direction.

9. The method according to claim 8, comprising decomposing the first, second, third, and fourth square waves using a Fourier Transform equation.

10. An apparatus comprising:
a processor; and
a memory including computer program code for one or more programs, the memory and the computer program code configured to, with the processor, cause the apparatus to perform the following,
form a first diffraction pattern in a first layer of a wafer;
form a second diffraction pattern in a second layer of the wafer, the second layer being formed over the first layer;
detect a first or a higher odd order signal in an X and a Y direction from each of the first and second diffraction patterns;
calculate a peak for each signal;
measure a delta value between peaks of the signals in the X direction and a delta value between peaks of the signals in the Y direction; and
calculate an overlay between the first and second layers based on the delta values.

11. The apparatus according to claim 10, wherein the apparatus is further caused to:
form the first diffraction pattern with a pitch of 60 nanometer (nm) to 800 nm.

12. The apparatus according to claim 10, wherein the apparatus is further caused to:
form the second diffraction pattern with a pitch of 160 nm to 1600 nm.

13. The apparatus according to claim 10, wherein the apparatus is further caused to:
form the second diffraction pattern overlapping the first diffraction pattern in a parallel direction, a perpendicular direction, or a parallel and perpendicular direction to the first diffraction pattern.

14. The apparatus according to claim 13, wherein the apparatus is further caused, with respect to detecting the first or higher odd order signal in the X and Y directions from each of the first and second diffraction patterns, to:
scan the first and second diffraction patterns in the X direction with a laser;
detect a first square wave from the first and second diffraction patterns;
decompose the first square wave into the first or higher odd order signal for each of the first and second diffraction patterns in the X direction;
scan the first and second diffraction patterns in the Y direction with a laser;
detect a second square wave from the first and second diffraction patterns; and
decompose the second square wave into the first or higher odd order signal for each of the first and second diffraction patterns in the Y direction.

15. The apparatus according to claim 14, wherein the apparatus is further caused to:
decompose the first and second square waves using a Fourier Transform equation.

16. The apparatus according to claim 10, wherein the apparatus is further caused to:
form the second diffraction pattern without overlapping the first diffraction pattern.

17. The apparatus according to claim 16, wherein the apparatus is further caused, with respect to detecting the first or higher odd order signal in the X and Y directions from the first and second diffraction patterns, to:
scan the first and second diffraction patterns in the X direction with a laser;
detect a first and a second square wave from the first and second diffraction patterns;
decompose the first and the second square wave into first and second first or higher odd order signals for each of the first and second diffraction patterns in the X direction;
scan the first and second diffraction patterns in the Y direction with a laser;
detect a third and a fourth square wave from the first and second diffraction patterns;
decompose the third and fourth square waves into third and fourth first or higher odd order signals for each of the first and second diffraction patterns in the Y direction.

18. The apparatus according to claim 17, wherein the apparatus is further caused to:
decompose the first, second, third, and fourth square waves using a Fourier Transform equation.

19. A method comprising:
forming a first diffraction pattern with a pitch of 80 nanometer (nm) to 800 nm in a first layer of a wafer;
forming a second diffraction pattern with a pitch of 160 nm to 1600 nm in a second layer of the wafer, the second diffraction pattern overlapping the first diffraction pattern in a parallel direction, a perpendicular direction, or a parallel and perpendicular direction to the first diffraction pattern;
detecting a first or a higher odd order signal in an X and a Y direction from the first and second diffraction patterns;
calculating a peak for each signal;
measuring a delta value between peaks of the signals in the X direction and a delta value between peaks of the signals in the Y direction; and
calculating an overlay between the first and second layers based on the delta values.

20. The method according to claim 19, comprising detecting the first or higher odd order signal in the X and Y directions from each of the first and second diffraction patterns by:
scanning the first and second diffraction patterns in the X direction with a laser;
detecting a first square wave from the first and second diffraction patterns;
decomposing the first square wave into the first or higher odd order signal for each of the first and second diffraction patterns in the X direction using a Fourier Transform equation;
scanning the first and second diffraction patterns in the Y direction with a laser;
detecting a second square wave from the first and second diffraction patterns; and
decomposing the second square wave into the first or higher odd order signal for each of the first and second diffraction patterns in the Y direction using the Fourier Transform equation.
